(19) United States
(12) Patent Application Publication
(10) Pub. No.: US 2014/0261158 A1
(43) Pub. Date: Sep. 18, 2014

(54) FURNANCE EMPLOYING COMPONENTS FOR USE WITH GRAPHITE HOT ZONE

(71) Applicant: ADVANCED RENEWABLEENERGY COMPANY, LLC, Nashua, NH (US)

(72) Inventors: Thomas DeWayne WENDEL, Nashua, NH (US); Matthew Gary KLOTZ, Mont Vernon, NH (US); David M KENT, Blackstone, MA (US); Nicholas Joseph SERPA, Merrimack, NH (US); Chandra P KHATTAK, Nashua, NH (US); Saurabh ULLAL, Hollis, NH (US)

(73) Assignee: ADVANCED RENEWABLEENERGY COMPANY, LLC, Nashua, NH (US)

(21) Appl. No.: 14/205,988

(22) Filed: Mar. 12, 2014

Related U.S. Application Data
(60) Provisional application No. 61/779,409, filed on Mar. 13, 2013.

(51) Int. Cl. C30B 11/00

(52) U.S. Cl. CPC C30B 11/002
USPC 117/81; 117/223

(57) ABSTRACT

A furnace for growing sapphire crystal in which the furnace comprises a furnace housing; a hot zone which comprises insulation and a heater which are both accommodated within the furnace housing; a crucible located within the hot zone and the crucible has an opening. Either a crucible lid covers the opening of the crucible, and the crucible lid has a first conduit which extends therefrom or a crucible enclosure surrounds at least a side wall and a top portion of the crucible and the crucible enclosure is impermeable to at least carbon preventing carbon contamination of a melt contained within the crucible.

This application claims the benefit of U.S. provisional application No. 61/779,409 filed Mar. 13, 2013.

### FIELD OF THE INVENTION

The present invention generally relates to crystal growth furnaces and hot zones and, more particularly, relates to providing a barrier formed between the crucible and the hot zone of the furnace, which is impermeable to graphite/carbon or any other undesired components and/or constituents, so as to prevent contamination of the sapphire crystal during crystal growth process.

### BACKGROUND OF THE INVENTION

Hot zones are components in high-temperature furnaces used for various applications, including the growth of crystals such as sapphire, silicon, and other similar materials. During crystal growth process, a hot zone typically includes at least one heating element and at least one insulating element surrounding the heating element. A charge material, located within a crucible, is melted within the hot zone and then gradually allowed to cool within the furnace thereby forming the desired crystal.

The insulating elements of a hot zone are typically formed from graphite (or other carbon-containing materials) and/or one or more refractory metals. In addition, due to their reduced cost, the heating elements may also be manufactured from graphite. Graphite hot zones are relatively inexpensive—compared to refractory metal hot zones—and also provide excellent insulation, but contamination of the melt, contained within the crucible during the crystal growing process, is a great concern. More specifically, any contamination, e.g., carbon atoms or other molecules which separate from either the graphite heating element and/or the graphite insulating element, as particles or gaseous species, can interact with the melt and cause one or more defects or imperfections within the crystal during the crystal growth process. Such defect(s) or imperfection(s) thereby cause poor furnace performance or a portion of the grown crystal to be unsatisfactory since such a defective portion of the crystal cannot be utilized for further processing and must be generally discarded.

In view of the above background, there is a need for a system and a method which prevents any carbon or the undesired components and/or constituents, from a graphite hot zone as well as other portions of the furnace, from interacting and contaminating a melt during crystal growth process.

### SUMMARY OF THE INVENTION

Wherefore, it is an object of the present invention to overcome the above mentioned shortcomings and drawbacks associated with the prior art.

An object of the present invention is to provide an improved furnace for growing crystals and, in particular, a sapphire crystal. The furnace includes a furnace housing, a hot zone comprising insulation and at least one heater, a crucible located within the hot zone, and a crucible lid located at and at least partially covering the opening of the crucible. The crucible lid includes a first conduit which extends vertically upward from the crucible lid and provides access to the interior chamber of the crucible. The crucible lid and the first conduit assist with further partitioning and/or segregation of a melt, contained within the crucible, from the remainder of the furnace

Another object of the present invention is to provide a furnace for growing sapphire crystal. The furnace includes a furnace housing, a hot zone comprising insulation and at least one heater, a crucible located within the hot zone, and a crucible enclosure surrounding at least a portion of an exterior wall and/or top opening of the crucible for preventing carbon or the undesired components and/or constituents, from a graphite hot zone as well as other portions of the furnace, from contaminating and interacting with the melt contained within the crucible during crystal growing process.

A still further object of the present invention is to provide an impermeable barrier between the melt, contained within the crucible, and the graphite hot zone(s) so as to prevent any undesired contamination of the melt, during the crystal growing process, and thereby minimize the possibility of any defects from occurring within the crystal during the crystal growing process.

Yet another object of the present invention is to slightly pressurize the interior chamber of the crucible with a desired (inert) gas, such as argon or helium for example, and slowly bleed off and/or exhaust a portion of the supplied desired (inert) gas into the remaining area of the furnace so as to minimize the flow of any contaminates, e.g., molecules, atoms or minute particles or constituents, from the hot zone into the interior chamber of the crucible.

A still further object of the present invention is to totally enclose or encase both the crucible as well as the melt contained therein, while located within the furnace, in order to prevent the migration of any carbon or other undesired atoms, molecules and/or impurities through the top opening of the crucible or through an exterior surface of the crucible and eventually migrating into and contaminating the melt, contained within the crucible, during the crystal growing process.

Still another object of the present invention is to completely, or at least sufficiently, partition and otherwise separate or segregate both the crucible and the melt, from a remainder of the furnace, e.g., the hot zone, the insulation, etc., while still permitting a pyrometer to be introduced into the interior chamber of the crucible and monitor the crystal during the crystal growing process.

Yet another object of the present invention is to completely line, coat or plate the entire exterior surface of the crucible with a material which is impermeable to carbon, and/or other undesired constituents, so as to prevent the flow or migration of carbon, and/or other undesired constituents, through the crucible wall and into the melt, contained within the crucible, during the crystal growing process.

The present invention also relates to a furnace for growing sapphire crystal, the furnace comprising: a furnace housing; a hot zone comprising insulation and at least one heater both being accommodated within the furnace housing; a crucible being located within the hot zone and the crucible having an opening; and a crucible lid covering at the opening of the crucible, and the crucible lid having a first conduit extending therefrom.

The present invention also relates to a furnace for growing sapphire crystal, the furnace comprising: a furnace housing; a hot zone comprising insulation and at least one heater both being accommodated within the furnace housing; a crucible being located within the hot zone and the crucible having an opening; and a crucible enclosure surrounding at least a portion of an exterior wall of the crucible with the crucible enclosure being impermeable to at least carbon.

The present invention additionally relates to a method of growing a sapphire crystal in a furnace which comprises a furnace housing; a hot zone which comprises insulation and at least one heater both accommodated within the furnace housing; a crucible located within the hot zone and the crucible having an opening; and at least one of a crucible enclosure, which is impermeable to at least carbon, covering at least the opening of the crucible and at least a portion of a side wall of the crucible or a crucible lid covering at the opening of the crucible and a first conduit extending from the crucible lid, the method comprising the step of: forming a barrier, via at least one of the crucible enclosure and the crucible lid and the first conduit, between a melt contained within the crucible and the hot zone of the furnace for preventing contamination of the melt, contained within the crucible, by carbon when growing the sapphire crystal in the furnace.

### BRIEF DESCRIPTION OF THE DRAWINGS

The accompanying drawings, which are incorporated in and constitute a part of the specification, illustrate various embodiments of the invention and together with the general description of the invention given above and the detailed description of the drawings given below, serve to explain the principles of the invention. It is to be appreciated that the accompanying drawings are not necessarily drawn to scale since the emphasis is instead placed on illustrating the principles of the invention. The invention will now be described, by way of example, with reference to the accompanying drawings in which:

FIG. 1 is a diagrammatic cross-sectional view of a furnace according to a first embodiment of the invention;

FIG. 2 is a diagrammatic cross-sectional view of a furnace according to a second embodiment of the invention;

FIG. 3 is a diagrammatic cross-sectional view of a furnace according to a third embodiment of the invention;

FIG. 4 is a diagrammatic cross-sectional view of a furnace according to a fourth embodiment of the invention;

FIG. 5 is a diagrammatic cross-sectional view of a furnace according to a fifth embodiment of the invention;

FIG. 6 is a diagrammatic cross-sectional view of a furnace according to a sixth embodiment of the invention;

FIG. 6A is a diagrammatic cross-sectional view of a furnace, similar to the FIG. 6, showing a crucible enclosure formed by a relatively thin lining, coating or layer of material;

FIG. 7 is a diagrammatic cross-sectional view of a furnace according to a seventh embodiment of the invention; and

FIG. 8 is a diagrammatic cross sectional view of a furnace according to an eighth embodiment of the invention.

### DETAILED DESCRIPTION OF THE INVENTION

The present invention relates to crystal growth by directional solidification of molten sapphire, such as the methods described in co-pending applications U.S. patent application Ser. Nos. 12/588,656 and 12/909,471, and the disclosures of each of those references is hereby incorporated by reference in their entireties.

The present invention will be understood by reference to the following detailed description which should be read in conjunction with the appended drawings. It is to be appreciated that the following detailed description, concerning various embodiments of implementing the present invention, is by way of example only and is not meant to limit, in any way, the scope of the present invention.

Referring now to FIG. 1, the system generally comprises a furnace 100 for growing sapphire crystal and the furnace 100 includes an exterior furnace housing 103. A heater 107 is accommodated within the furnace 100 along with conventional insulation 105, in a conventional manner, and, the heater 107 and the insulation 105 together form what is commonly referred to as the “hot zone”, and thus a further detail description concerning the same is not provided. The insulation 105 generally comprises planar top shield insulation 106, cylindrical side shield insulation 104, and generally planar bottom shield insulation 108 which together insulate the top, side and bottom of the furnace. The top shield insulation 106 typically includes a centrally located hole 123 for permitting desired instrumentation 121, such as a probe rod or a pyrometer, to pass therethrough and enter inside the furnace and into an interior chamber 110 of a crucible 109 to detect the desired parameter(s), e.g., the temperature, the rate of growth of the crystal, etc. The crucible 109 is generally located within and accommodated by the hot zone of the furnace 100. The interior chamber 110 of the crucible 109 is typically filled with a desired seed material 115 as well as a desired source material (not shown in detail in this Figure). Prior to commencing growth of the crystal, all of the source material as well as a portion of the seed material 115, e.g., only the top portion but not the base portion of the seed material 115 contained within the interior chamber 110 of the crucible, must be melted so that, immediately prior to crystal growth, the crucible contains both a sapphire melt 113 and some solid seed crystal 115.

A top end of an adjustable cooling rod 116 carries a circular disk shaped support (e.g., about 40 mm in diameter). A central bottom portion of the crucible 109 has a mating recess or indentation which facilitates releasable support of the crucible 109 by the circular disk shaped support of the adjustable cooling rod. The circular disk shaped support is sized to be captively received within the circular recess or indentation of the crucible 109 and facilitate secure but releasable retention of the crucible 109 so that the cooling rod can facilitate convey the crucible 109 vertically upwardly and downwardly, as is conventional in the art, in order to control growth of the crystal during the crystal growing process. A cooling fluid supply conduit (not shown in detail) is accommodated centrally within the cooling rod 116 for supplying a cooling fluid directly to a bottom surface of the circular disk shaped support to facilitate cooling thereof. The circular disk shaped support, in turn, facilitates cooling of only the central bottom portion of the crucible 109 and the supported seed crystal 115 so as to prevent the seed crystal 115 from completely melting. The cooling fluid is conveyed away from the circular disk shaped support by flowing vertically downward along the exterior surface of the cooling fluid supply conduit and the interior surface of the cooling rod 116.

The instrument hole 123 provides access to the interior chamber 110 of the crucible. The instrument hole 123 is shown in a central portion of the furnace 100 but, it is to be appreciated, that the instrument hole 123 may be located in any other desired location. A top opening of the crucible 109 is typically covered or sealed by a crucible lid 117 which segregates and/or partitions the interior chamber 110 of the crucible from a remainder of the interior compartment 99 of the furnace 100. As generally shown in FIG. 1, a central portion of the crucible lid 117 has a first (crucible lid) conduit 119 which extends substantially normal to the crucible lid 117 toward the hole 123 and extends through the top shield insulation 106.

Preferably the first conduit 119 and the hole 123 are aligned with one another to facilitate passing the desired instrumentation 121, such as the probe rod, through both the hole 123 of the top shield insulation 106 and the first conduit 119 of the crucible lid 117 and into the interior chamber 110 of the crucible 109 to facilitate access the melt 113 and/or the seed crystal 115 contained within the crucible. The first conduit 119 is arranged and designed for physically shielding the probe rod 121 from being exposed to carbonaceous deposits and other contaminants which are contained within the interior compartment 99 of the furnace and thereby assist with avoiding contamination of the crystal, by the probe rod 121, during the crystal growing process.

The first conduit 119 and the crucible lid 117 may be formed, for example, from a refractory metal such as tungsten, molybdenum, tantalum and/or iridium or any combination(s) thereof. The inventors believe that such refractory metals react with the carbonaceous materials and use of such material, to manufacture both the crucible lid 117 as well as the first conduit 119, assists with preventing, or minimizing to a great extent, any carbonaceous contaminants and/or other constituents, of the hot zone, from entering the interior chamber 110 of the crucible 109 and contaminating the melt during the crystal growing process.

An exhaust port 111, may be located along the bottom portion of the furnace 100, to provide an outlet for exhausting a purge gas and/or undesired constituents or contaminants from the furnace 100 and also preventing pressurization of the furnace 100. A pump 112 communicates with the exhaust port 111, provided along the bottom portion of the furnace 100, to facilitate exhausting of the desired gas(es)/contaminants/constituents from the furnace 100.

With reference now to FIG. 2, a second embodiment of the present invention will now be described. It is to be appreciated that this configuration of the furnace 100 is similar to the embodiment shown in FIG. 1 except that, according to this embodiment, a first (crucible lid) conduit 119 extends from the crucible lid 117 to and through the hole 123 formed in the top shield insulation 106. As a result of this arrangement, the first conduit 119 passes through hole 123 so that the instrumentation 121, such as probe rod, may pass through and along the first conduit 119 and directly communicate and access the melt 113 contained within the interior chamber 110 of the crucible 109 without communicating or interacting with the interior compartment 99 of the furnace 100. That is, the first conduit 119 completely physically shields the probe rod 121 from exposure to any carbonaceous contaminants or other undesired constituents or contaminants, from either the insulation 105 and/or the heater 107, which are contained within the interior compartment 99 of the furnace 100.

Preferably, the first conduit 119 is manufactured from either molybdenum, tungsten, tantalum and/or iridium or any combination(s) thereof which is particularly useful in thereby reacting with any carbon contamination and/or other undesired constituents from the insulation 105 and/or the heater 107 and thereby preventing such carbon contamination and/or other undesired constituents or contaminants from entering into the interior chamber 110 of the crucible 109 and contaminating the melt 113, either before or during the crystal growing process.

At least one purge gas exhaust port 111, may be located along the side or bottom portion of the furnace 100, to provide an outlet for exhausting the aluminum oxide vapors and/or other contaminate(s) or gas(es) from the furnace 100. A pump 112 communicates with the purge gas exhaust port 111 to facilitate exhausting of the aluminum oxide vapors and/or other contaminate(s) or gas(es) from the furnace 100.

With reference now to FIG. 3, a third embodiment of the present invention will now be described. It is to be appreciated that this configuration of the furnace 100 is similar to the embodiment shown in FIG. 2 except that, according to this embodiment, the first (crucible lid) conduit 119 extends completely through and projects out from the furnace housing 103 and thus directly communicates with an external environment surrounding the furnace 100. According to this embodiment, an inert gas source S is connected to an inlet of the first conduit 119 for supplying a desired inert purge gas (e.g., such as argon or helium, for example) thereto. The inert purge gas is conveyed along the length of the first conduit 119 into the interior chamber 110 of the crucible 109 and utilized to create a slight positive pressure within the interior chamber 110 of the crucible 109. The inventors have found that higher furnace pressures (e.g., pressures above 10 Torr, for example) during the melting of the charge material and other crystal growth process steps result in reduced carbon contamination of the crucible surface.

As generally shown in this figure, the inert purging gas is supplied to the upper inlet end of the first conduit 119 and the purging gas flows along the first conduit 119 into the interior chamber 110 of the crucible 109. The purge gas typically exits and/or exhausts from the interior chamber 110 of the crucible 109 via one or more small gaps formed between a top perimeter edge of the crucible 109 and mating, bottom facing surface of the crucible lid 117 or along one or more an annular exhaust ports (not shown in detail) formed at the interface between the crucible lid 117 and the bottom second end of the first conduit 119.

At least one purge gas exhaust port 111, typically located along the bottom portion of the furnace 100, provides a furnace outlet for exhausting the purge gas from the furnace 100 and preventing pressurization of the furnace 100. The purge gas exhaust port 111 facilitates creation of a flow of the purging gas from the inert gas source S, into the interior chamber 110 of the crucible 109, into the interior compartment 99 of the furnace 100 and eventually out through the purge gas exhaust port 111 and into the external environment. A pump 112 communicates with the purge gas exhaust port 111, located along the bottom portion of the furnace 100 to facilitate exhausting of the purge gas from the furnace 100. According to this embodiment, the first conduit 119 physically shields the probe rod 121 from direct exposure to any carbon contaminants or other constituents from the insulation 105 and the heater 107 as the probe 121 passes along the first conduit 119 directly into the interior chamber 110 of the crucible 109. This embodiment also has the further advantage of actively drawing any aluminum oxide vapors away from the interior chamber 110 of the crucible 109 (via positive pressure created within the interior chamber 110 of the crucible) while simultaneously preventing any carbonaceous contaminants and/or other constituents or contaminants of the insulation 105 and/or the heater 107 from flowing, migrating and/or entering into the interior chamber 110 and reacting with the melt 113 contained within the crucible 109 during the growing process.

With reference now to FIG. 4, a fourth embodiment of the present invention will now be described. It is to be appreciated that this configuration of the furnace is similar to the embodiment shown in FIG. 3 except the crucible lid includes both a centrally located first conduit 119 and a concentric outer second conduit 120 which completely surrounds the first conduit 119. The first and the second conduits 119, 120 both extend from the hole 123, formed in the top shield insulation 106, to the central opening formed in the crucible lid 117. Although the first conduit 119 is shown enclosed and surrounded by the second conduit 120, it is to be appreciated that alternative configurations of the two conduits can be employed without departing from the spirit and scope of the present invention.

According to this embodiment, an inert gas source S is typically connected and communicates with a first inlet of the first conduit 119 which projects and extends from a top exterior surface of the furnace housing 103 so that a desired purge gas (e.g., such as argon or helium, for example) may be supplied to an inlet of the first conduit 119 and permitted to flow therealong into the interior chamber 110 of the crucible 109 and thereby establish a slight positive pressure of the (inert) purge gas within the interior chamber 110 of the crucible 109. The second conduit 120 serves as an exhaust flow path which facilitates exhausting the (inert) purge gas from the interior chamber 110 of the crucible 109 and thereby ensures that any aluminum oxide vapors, which are generated by the melt, are transported and conveyed away from the interior chamber 110 of the crucible 109 and exhausted outside the interior chamber 110 of the crucible 109.

As generally shown in this figure, the (inert) purging gas, exhausted from crucible 109, generally flows vertically upward, along a purge gas exhaust port 111 formed between the exterior surface of the first conduit 119 and the inwardly facing surface of the second conduit 120 and the purge gas is eventually exhausted out into the surrounding environment located vertically above the furnace 100. According to this embodiment, an exhaust port, located in a lower section of the furnace, and a pump are typically not required, but may be utilized if so desired or required. The purge gas exhaust port 111 facilitates exhausting of the (inert) purge gas, and any aluminum oxide vapors, from the furnace 100 and also prevents pressurization of the furnace 100. The purge gas exhaust port 111 creates a flow of the (inert) purging gas from the inert gas source S, into the interior chamber 110 of the crucible 109, and eventually out through the purge gas exhaust port 111 and into the external environment as well as flow of any aluminum oxide vapors, from the melt 113 eventually out through the purge gas exhaust port 111 and into the external environment.

As alluded to above, a purging gas facilitates slightly increasing the pressure of the interior chamber 110 of the crucible 109. In addition, this embodiment also has the advantage of actively drawing aluminum oxide vapors away from the interior chamber 110 of the crucible 109 to a location external to the furnace housing 103 while simultaneously preventing carbonaceous and other contamination, from the insulation 105 and/or the heater 107, from entering into the slightly higher pressure interior chamber 110 of the crucible 109 and reacting with the melt 113 contained within the crucible 109.

With reference now to FIG. 5, a still further embodiment of the present invention will now be described. This embodiment, of the present invention, is directed at preventing carbon from the hot zone, in either particulate(s) or gaseous form, from interacting with the exposed surface of the crucible 109 and the crucible lid 117 and eventually migrating therethrough and contaminating the melt 113. As generally shown in this Figure, a crucible enclosure 135 surrounds at least a major portion of an exterior side wall of the crucible 109 and generally segregates the crucible 109 from a remainder of the interior compartment 99 of the furnace 100. As generally shown, the crucible enclosure 135 generally surrounds the entire exterior wall or surface of the crucible 109 and comprises a crucible lid section which completely covers the top opening of the crucible 109 so as to minimize possibility of any carbon constituents, or other desired components or contaminants, from interacting with the melt 113 contained within interior chamber 110 of the crucible 109, during the crystal growing process.

The crucible lid section of the crucible enclosure 135 has a centrally located opening therein and a first conduit 119 extends substantially normal to a vertically upper most portion (e.g., the crucible lid section) of the crucible enclosure 135 toward the hole 123, formed in the top shield insulation 106. A second conduit 120 extends from the hole 123, formed in the top shield insulation 106, vertically downward toward an inlet portion of the first conduit 119. The second conduit 120 concentrically surrounds the inlet portion of the first conduit 119. The second conduit 120, the first conduit 119 and the crucible enclosure 135 facilitate communication between desired instrumentation 121 and the interior chamber 110 of the crucible 109. The crucible enclosure 135, the second conduit 120, and the first conduit 119, according to this embodiment, function as a barrier/partition which separate the melt 113 contained within the crucible 109 from the insulation 105 and the heater 107, forming the graphite hot zone of the furnace 100, thereby rendering it more difficult for any carbonaceous components, or other undesired constituents, from eventually interacting with the melt 113 contained within the crucible 109. The vertical lowermost portion of the second conduit 120 receives and permits relative motion with respect to the vertically uppermost inlet portion of the first conduit 119 so as to permit the crucible 109 to move vertically up and down, during the crystal growing process.

If desired, an inert gas source S may be connected with the inlet of the first conduit 119 or the second conduit 120 to supply an inert gas to the interior chamber 110 of the crucible 109. Alternatively, or in addition, an exhaust port 111 may be located in a lower section of the furnace 100 and a pump 112 may be coupled thereto to facilitate exhausting of the (inert) purge gas, and any aluminum oxide vapors, from the furnace 100 and also preventing pressurization of the furnace 100.

With reference now to FIG. 6, a sixth embodiment of the present invention will now be described. It is to be appreciated that this configuration of the furnace is similar to the embodiment shown in FIG. 5. According to this embodiment, the crucible enclosure 135 has at least one contoured surface that closely mirrors or follows an exterior wall or surface of the crucible 109. For example, as shown in the embodiment of FIG. 6, the crucible enclosure 135 may be shaped so as to generally mirror or substantially coincide with the exterior shape of the crucible 109 and thereby assist with more completely enclosing the crucible 109, as well as the melt 113 contained therein, and separating the same from the interior compartment 99 of the furnace 100.

Alternatively, as diagrammatically shown in FIG. 6A, at least the exterior surface of the crucible 109 may be lined with a relatively thin lining, coating or layer of material which forms a crucible enclosure 135 that prevents the passaged or migration of any carbon or other undesired atoms, molecules and/or impurities through the crucible enclosure 135 and the surface the crucible 109 and into either the interior chamber 110 and/or the melt 113, contained within the crucible 109, during the crystal growing process. The lining, coating or layer of material, which forms a crucible enclosure 135, is selected from the group consisting of molybdenum, tungsten, tantalum and iridium. As with the previous embodiments, typically a crucible lid 117 will cover the opening of the crucible 109.

With reference now to FIG. 7, a seventh embodiment of the present invention will now be described. It is to be appreciated that this configuration of the furnace is generally a combination of the embodiment shown in FIGS. 1 and 6. According to this embodiment, the crucible enclosure 135 is formed as first and second crucible enclosure components 136, 137 which, when mated together with one another as shown in the Figure, form a crucible enclosure 135 which generally completely surrounds, encases and encloses the crucible 109. As generally shown, the second crucible enclosure component 137 is supported by a top portion of the control rod 116 while the first crucible enclosure component 136 generally comprises an inverted cylindrical container and a perimeter surface thereof mates with and is releasably supported by the second crucible enclosure component 137. In addition, according to this embodiment, at least one first conduit 119 is supported by a top of a vertically uppermost (crucible lid) section of the first crucible enclosure component 136. The first conduit 119 extends substantially normal to the uppermost (crucible lid) section of the first crucible enclosure component 136 toward the hole 123 which extends through the top shield insulation 106. Preferably the first conduit 119 and the hole 123 are aligned with one another to facilitate passing the desired instrumentation 121 through both the hole 123, of the top shield insulation 106, and the first conduit 119 and into the interior chamber 110 of the crucible 109, to facilitate access to the melt 113 and the seed crystal 115 contained within the crucible 109. The first conduit 119 is arranged and designed for physically shielding the probe rod 121 from being exposed to carbonaceous deposits and other contaminants which are contained within the interior compartment 99 of the furnace 100 and thereby assist with avoiding contamination of the crystal during the crystal growing process.

A second conduit 120 concentrically surrounds the inlet portion of the first conduit 119. The vertical lowermost portion of the second conduit 120 receives and permits relative movement with respect to the vertically uppermost inlet portion of the first conduit 119 so as to permit the crucible 109 to move vertically up and down, during the crystal growing process.

It is to be appreciated that the crucible enclosure 135 or 136 may be used in conjunction with any of the embodiments shown in FIGS. 1-4. For example, a crucible enclosure 135 may be used with a crucible lid 117 having a first conduit 119 for introducing a purge gas, from a purge gas source S, and establishing a positive pressure inside the interior chamber 110 of the crucible 109, and a second conduit for withdrawing any undesired vapors from inside the interior chamber 110 of the crucible 109 to a location outside the furnace housing 103. Alternatively, or in addition, an exhaust port 111 may be located in a lower section of the furnace 100 and a pump 112 may be coupled thereto to facilitate exhausting of the (inert) purge gas, and any aluminum oxide vapors, from the furnace 100 and also preventing pressurization of the furnace 100.

With reference now to FIG. 8, an eighth embodiment of the present invention will now be described. It is to be appreciated that this configuration of the furnace 100 is similar to the embodiments shown in FIGS. 4 and 5. According to this embodiment, a crucible enclosure 135 includes a vertically upper most crucible lid section 117 which covers the opening of the crucible 109 and a vertically lower most section of the crucible enclosure 135 surrounds at least a portion of an exterior side wall of the crucible 109 so as to segregate the crucible 109 from a remainder of the interior compartment 99 of the furnace 100. As generally shown, the crucible enclosure 135 generally surrounds the entire exterior wall or surface of the crucible 109 as well as the top opening of the crucible 109 so as to minimize the possibility of any carbon constituents, or other desired components, from interacting with the melt 113 contained within interior chamber 110 of the crucible 109.

The vertically upper most crucible lid section 117 of the crucible enclosure 135 has a centrally located opening therein and a first conduit 119 extends substantially normal thereto toward and at least partially passes through the hole 123. A second conduit 120 also extends from a vertically uppermost portion of the crucible enclosure 135 toward the hole 123. However, the second conduit 120 only extends partially toward the hole 123, e.g., only about ⅓ to about one half of the way or so. The second conduit 120 concentrically surrounds a vertically lower portion of the first conduit 119. The first conduit 119 and the crucible enclosure 135 facilitate communication between the instrumentation 121, if provided, and the interior chamber 110 of the crucible 109. The crucible enclosure 135 and the first conduit 119, according to this embodiment, function as a barrier/partition which separate the melt 113 contained within the crucible 109 from the insulation 105 and the heater 107, forming the graphite hot zone of the furnace 100, thereby rendering it more difficult for any carbonaceous components, or other undesired constituents, from eventually interacting with the melt 113 contained within the crucible 109.

An inert gas source S is connected to and communicates with a first inlet of the first conduit 119 so that a desired purge gas (e.g., such as argon or helium, for example) may be supplied to the first conduit 119 and permitted to flow therealong into the interior chamber 110 of the crucible 109 and thereby establish a slight positive pressure of the (inert) purge gas within the interior chamber 110 of the crucible 109. The second conduit 120 serves as an exhaust flow path which facilitates exhausting the (inert) purge gas, as well as any aluminum oxide vapors which are generated by the melt, from the interior chamber 110 of the crucible 109 directly into the interior compartment 99 of the furnace 100.

As generally shown in this figure, the (inert) purging gas and any aluminum oxide vapors, exhausted from crucible 109, flow toward at least one purge gas exhaust port 111, typically located along a bottom or a side wall portion of the furnace 100. A pump 112 communicates with the purge gas exhaust port 111 to facilitate exhausting of the (inert) purge gas and any aluminum oxide vapors from the furnace 100 and also prevents pressurization of the furnace 100. The purge gas exhaust port 111 creates a flow of the (inert) purging gas from the inert gas source S, into the interior chamber 110 of the crucible 109, into the interior compartment 99 of the furnace 100 and eventually out through the purge gas exhaust port 111 and into the external environment and also forms a flow path for any aluminum oxide vapors, generated by the melt 113, into the interior compartment 99 of the furnace 100 and eventually out through the purge gas exhaust port 111 and into the external environment. That is, this embodiment has the advantage of actively drawing aluminum oxide vapors away from the interior chamber 110 of the crucible 109 to a location external to the furnace housing 103 while simultaneously preventing carbonaceous and other contamination, from the insulation 105 and/or the heater 107, from entering into the interior chamber 110 of the crucible 109 and reacting with the melt 113 contained within the crucible 109.

Typically, a conventional seal (not shown) is located at the interface between the furnace housing 103 and any portion of either the first conduit 119 or the second conduit 120 which extends or projects outside the furnace 100. Such seal assist with minimizing the escape of heat and/or hot gases from the furnace 100. In addition, while the hole 123, the first conduit 119 and the second conduit 120 have sufficiently close tolerances, tolerances must be sufficiently large so as permit relative movement between those components as the crucible 109 moves vertically upward and downward, within the hot zone, during crystal growth process.

It is to be appreciated that the gas flow patterns, diagrammatically shown in the drawings, are merely for illustrative purposes only and a variety of other flow patterns and arrangements would be readily apparent to those skilled in the art, without departing from the spirit and scope of the present invention.

While various embodiments of the present invention have been described in detail, it is apparent that various modifications and alterations of those embodiments will occur to and/or be readily apparent those skilled in the art. However, it is to be expressly understood that such modifications and alterations are considered to fall within the spirit and scope of the present invention, as set forth in the appended claims. Further, the invention(s) described herein is capable of other embodiments and of being practiced or of being carried out in various other related ways. In addition, it is to be understood that the phraseology and terminology used herein is for the purpose of description and should not be regarded as limiting. The use of “including,” “comprising,” or “having,” and variations thereof, are meant to encompass the items listed thereafter and equivalents thereof as well as additional items.

Since certain changes may be made in the above described without departing from the spirit and scope of the invention herein involved, it is intended that all of the subject matter of the above description or shown in the accompanying drawings shall be interpreted merely as examples illustrating the inventive concept herein and shall not be construed as limiting the invention. All of the illustrated embodiments show a probe rod. It is to be appreciated in instances where a probe rod is not required, isolation of the interior chamber of the crucible, from a remainder of the furnace, may be simplified.

Wherefore, we claim:

1. A furnace for growing sapphire crystal, the furnace comprising:
a furnace housing;
a hot zone comprising insulation and at least one heater both being accommodated within the furnace housing;
a crucible being located within the hot zone and the crucible having an opening; and
a crucible lid covering at the opening of the crucible, and the crucible lid having a first conduit extending therefrom.

2. The furnace according to claim 1, wherein the first conduit extends from the crucible lid to a location located exterior to or vertically above the hot zone.

3. The furnace according to claim 1, wherein the first conduit extends through the furnace housing to a location located exterior to the furnace housing.

4. The furnace according to claim 3, wherein an external gas source is connected to an inlet of the first conduit for supplying a gas, through the crucible lid, into an interior chamber of the crucible.

5. The furnace according to claim 1, wherein the crucible lid includes a first conduit and a concentric second conduit, the first conduit extends through the furnace housing to a location located exterior thereof, and an external gas source is connected to an inlet of the first conduit for supplying a gas to the crucible.

6. The furnace according to claim 1, wherein the crucible lid and the first conduit each comprise a material selected from the group consisting of molybdenum, tungsten, tantalum and iridium.

7. The furnace according to claim 1, wherein the furnace is capable of operating at pressures above 10 Torr.

8. The furnace according to claim 1, wherein the furnace has at least one exhaust port which communicates with a pump for exhausting at least one of a purge gas and generated aluminum oxide vapor from the furnace.

9. A furnace for growing sapphire crystal, the furnace comprising:
a furnace housing;
a hot zone comprising insulation and at least one heater both being accommodated within the furnace housing;
a crucible being located within the hot zone and the crucible having an opening; and
a crucible enclosure surrounding at least a portion of an exterior wall of the crucible and the crucible enclosure being impermeable to at least carbon.

10. The furnace according to claim 9, wherein the crucible enclosure is formed from a material selected from the group consisting of molybdenum, tungsten, tantalum and iridium.

11. The furnace according to claim 9, wherein the crucible enclosure is formed by coating the crucible with a layer of material selected from the group consisting of molybdenum, tungsten, tantalum and iridium.

12. The furnace according to claim 9, further comprising a crucible lid for covering the opening of the crucible, and the crucible lid has a first conduit which extends vertically therefrom.

13. The furnace according to claim 12, wherein the first conduit extends to a location which is located exterior to the hot zone.

14. The furnace according to claim 13, wherein the first conduit extends through the furnace housing to a location which is located exterior to the furnace housing.

15. The furnace according to claim 14, wherein an external gas source is connected to the first conduit for supplying a gas to the crucible.

16. The furnace according to claim 12, wherein the crucible lid includes a first conduit and a second conduit, the first conduit extends through the furnace housing to a location located exterior to the furnace housing, and an external gas source is connected to an inlet of the first conduit for supplying a desired gas to the crucible.

17. The furnace according to claim 9, wherein the crucible enclosure has at least one contoured surface which follows a contour of the exterior wall of the crucible.

18. The furnace according to claim 9, wherein the crucible enclosure is at least impermeable to carbon so as to prevent carbon from passing through the crucible enclosure and communicating with a melt contained within an interior chamber of the crucible.

19. The furnace according to claim 9, wherein the crucible lid includes at least a first conduit which extends through the furnace housing to a location located exterior to the furnace housing, an external gas source is connected to an inlet or the first conduit for supplying a desired gas to an interior chamber of the crucible, and the furnace housing has a gas exhaust port which facilitate exhausting gases from the furnace and facilitates flow of the gas from the external gas source to the interior chamber of the crucible, into an interior compartment of the furnace and out through the gas exhaust port for preventing pressurization of the furnace.

20. A method of growing a sapphire crystal in a furnace which comprises a furnace housing; a hot zone which comprises insulation and at least one heater both accommodated within the furnace housing; a crucible located within the hot zone and the crucible having an opening; and at least one of a crucible enclosure, which is impermeable to at least carbon, covering at least the opening of the crucible and at least a portion of a side wall of the crucible or a crucible lid covering at the opening of the crucible and a first conduit extending from the crucible lid, the method comprising the step of:
forming a barrier, via at least one of the crucible enclosure and the crucible lid and the first conduit, between a melt contained within the crucible and the hot zone of the furnace for preventing contamination of the melt, contained within the crucible, by carbon when growing the sapphire crystal in the furnace.
